(19) United States
(12) Patent Application Publication
(10) Pub. No.: US 2026/0104446 A1
(43) Pub. Date: Apr. 16, 2026

(54) METHOD FOR TESTING AT LEAST ONE BYPASS DIODE IN AN APPARATUS COMPRISING AT LEAST ONE PHOTOVOLTAIC MODULE IN OPERATION

(71) Applicant: ELECTRICITE DE FRANCE, PARIS (FR)

(72) Inventors: Julien DUPUIS, BOIS LE ROI (FR); Valentin ACHARD, PALAISEAU (FR)

(73) Assignee: ELECTRICITE DE FRANCE, PARIS (FR)

(21) Appl. No.: 19/114,171

(22) PCT Filed: Sep. 14, 2023
(86) PCT No.: PCT/EP2023/075217

§ 371 Date: Mar. 21, 2025

(30) Foreign Application Priority Data
Sep. 21, 2022 (FR) FR2209577

(51) Int. Cl. G01R 31/26; G01J 5/08; H02S 40/10; H02S 50/00; H10F 19/70

(52) U.S. Cl. CPC G01R 31/2632; G01J 5/0859; H02S 40/10; H02S 50/00; H10F 19/70

(57) ABSTRACT

A method for testing at least one bypass diode in a photovoltaic system including at least one photovoltaic module that is in operation, the photovoltaic module includes at least one string of photovoltaic cells that are connected to a bypass diode dedicated to this string, the method includes: shading a portion of the cells of the string so as to cause a switch to bypass mode through the diode, this switch causing an increase in the temperature of the diode if the diode is in an operational state; measuring at least one temperature of the diode; and comparing the measured temperature with a threshold in order to deduce a state of the diode.

### TECHNICAL FIELD

The present disclosure relates to the field of photovoltaic modules or solar panels, and in particular concerns a method for testing at least one bypass diode on a system comprising at least one photovoltaic module that is in operation, as well as a device for implementing such a method.

### BACKGROUND

Bypass diodes are electronic components which, when placed to bypass strings of photovoltaic cells, allow limiting production losses from the photovoltaic module in the event of a cell failure.

The principle of using these bypass diodes is described below.

In a photovoltaic module comprising a plurality of photovoltaic cells, a partially shaded cell leads to a loss of current. For completely opaque objects such as leaves, the drop in the current that is output from the cell will be proportional to the surface area of the obscured cell.

When a string of cells in series is close to short-circuiting, then the forward bias voltage of all the cells will reverse bias the shaded cell in order to operate as a receiver. A “hot spot” phenomenon occurs when a large number of cells connected in series cause reverse bias across the shaded cell, leading to the dissipation of a large amount of power in the shaded cell. This large dissipation of power occurring in a single cell will result in a localized hot spot that can cause the destruction of at least that cell, and may disrupt the performance of the entire module.

The destructive effects of a hot spot can be circumvented by using a bypass diode. If a solar cell is reverse biased due to a current imbalance between several cells connected in series, then the bypass diode will become conductive, allowing current to flow through the external circuit that passes through the bypass diode.

In practice, placing a bypass diode for each cell is too expensive and is not easy to achieve. Bypass diodes are therefore generally placed on strings of cells. Each string has for example between eighteen and twenty-six cells. Each module generally comprises three strings of cells and three bypass diodes respectively associated with each string of cells.

Diagnosing the operating status of bypass diodes is important to maximizing the production of photovoltaic modules.

Indeed, there are two failure modes for a bypass diode: short circuit and open circuit. In the first case, a failure of the bypass diode that is related to a malfunction of one or more photovoltaic cells, due to shading or a short circuit or other causes, results in a loss of production of the photovoltaic module. In the second case, an open circuit failure can, in the worst case, result in a total loss of power from the panel.

It is known to characterize the operation of bypass diodes automatically. In particular, there is the known electrical detection, which uses the Intensity/voltage (I/V) curves of the power supplied by the modules. Another technique consists of digital detection by machine learning (fuzzy logic). A third known technique is statistical detection which makes use of a statistical hypothesis test also known as a T-test.

Such techniques are all based on analyzing the production curves of the photovoltaic module. This analysis is complex to implement on a string of modules, where the I/V curves of several photovoltaic modules are combined.

In addition, when the bypass diode is defective and remains in pass-through mode, detection of this defect is not guaranteed because electrical inspections on solar installations are often conducted on the system in general.

Furthermore, when the bypass diode is defective and remains closed during operation, it will not be detected as defective in the absence of an additional defect in the photovoltaic module because the latter will operate normally. However, in the event of a defect or of partial or permanent shading, the defective diode will not play its protective role and the shaded photovoltaic cells of the module run the risk of reaching a temperature of several hundred degrees Celsius, which could compromise the integrity of the photovoltaic module, or even cause a fire in extreme cases.

In addition, no technique allows completely testing the operation of a bypass diode during operation of the photovoltaic module in a solar power plant or photovoltaic system.

For example, one may make use of infrared cameras on drones or aircraft, but diodes that remain stuck in open mode will not be seen.

There is therefore a need to have a test of at least one bypass diode in a system comprising at least one photovoltaic module that is in operation.

### SUMMARY

The present disclosure improves the situation.

A method is proposed for testing at least one bypass diode in a photovoltaic system comprising at least one photovoltaic module that is in operation, said photovoltaic module comprising at least one string of photovoltaic cells connected to a bypass diode dedicated to said string, the method comprising:
a. shading a portion of the cells of said string so as to cause a switch to bypass mode through said diode, said bypass mode causing an increase in the temperature of the diode if the diode is in an operational state;
b. measuring at least one temperature of the diode; and
c. comparing the measured temperature with a threshold in order to deduce a state of said diode.

“State of the diode” is understood to mean at least the fact of whether or not it is in operation. Thus, “operational state of the diode” may designate at least the fact that the diode is in operation and is usable in the module. It is possible, in a more detailed manner, to characterize its operation by precisely recording its temperature or a variation in its temperature, for example.

The concept of “threshold” is a general one. It may involve measuring the temperature of the diode at another time (for example which precedes the moment of switching to bypass mode), or, for example, measuring the temperature of another element such as the photovoltaic module itself or the temperature of the string of cells to which the diode being tested is attached, or of an area linked to the diode, or of a fixed temperature such as the ambient temperature (for example 25° C.).

Activation of the diode, if it is in an operational state, will generate localized heating which will be detected by measuring the temperature and will be characterized by comparing it to said threshold.

If the diode is not in an operational state, no temperature variation will be observed there.

If the temperature of the diode is measured at the moment before switching to bypass mode, which is the moment when it becomes conductive, and if this temperature constituting said threshold is substantially equal to the ambient temperature and no variation in the temperature of the diode is observed after switching, then it can be concluded that the diode is defective, being stuck in open circuit mode.

If the temperature of the diode, measured after switching, is compared to the threshold corresponding to the temperature of the diode measured at the moment before switching, and if this temperature constituting the threshold is higher than the ambient temperature and no variation in the temperature of the diode is observed after switching, then it can be concluded that the diode is defective, being stuck in short circuit mode.

The temperature of the diode may be the temperature of the diode itself, of the string in which it is located, or even of the module.

The detection of one or more defective diodes may allow preventing potential safety hazards and/or improving the electrical production of the system when it comprises a plurality of photovoltaic modules. In addition, other related defects such as one or more defective photovoltaic cells may be detected using the method according to the invention, in particular by taking temperature measurements.

Step b is implemented after step a.

The photovoltaic module advantageously comprises cells that may be chosen from the group consisting of half-cells, full cells, so-called “shingled” cells cut into five or six strips, and thin-film cells, for example cadmium tellurium (CdTe), based on copper, indium, gallium, and selenium (CIGS), based on gallium arsenide GaAs, etc.

The system advantageously comprises several photovoltaic modules arranged side by side in pairs and each comprising a plurality of strings each comprising a plurality of cells and each connected to a bypass diode.

The features set forth in the following paragraphs may optionally be implemented, independently of each other or in combination with each other:

When the photovoltaic module comprises several strings of cells and several diodes associated with said strings, the switch to bypass mode may be caused by partial shading over several strings, in which case several diodes are activated simultaneously, and their state may be tested simultaneously using the method according to the invention.

The method may be implemented on several adjacent photovoltaic modules. Step a may be implemented on several strings of cells simultaneously, or even for several photovoltaic modules, depending on the configuration of the assembly (called a stand) of photovoltaic modules, which may cause the simultaneous switching to bypass mode of several strings within a same photovoltaic module and/or of several strings distributed over different photovoltaic modules, for example arranged side by side in pairs.

At least steps a and b are preferably implemented using a robot, in particular a cleaning robot for photovoltaic modules. To do this, said robot is advantageously configured to shade said portion of the cells. The robot preferably comprises a thermal sensor, in particular a thermal camera, to measure said at least one temperature of the diode. The robot is preferably fixed to the photovoltaic module or photovoltaic system and is movable in translation relative thereto along a direction of advancement.

According to this embodiment, the method may use the cleaning robot, for example one actually present on the system comprising the photovoltaic module(s), to shade a portion of the cells, but another robot or another device, or a dedicated device, may alternatively be provided, in particular another device integral to the module or photovoltaic system and movable in translation relative thereto.

In the case where the cleaning robot is used, the latter may be moved over the photovoltaic module(s) in order to participate in testing the operation of the diode(s).

The advantage of using the cleaning robot is that it is possible to combine the cleaning of the module(s) and the testing of the operation of the diode(s), the testing then not significantly increasing the maintenance cost.

Step b may be implemented after a time interval following the implementation of step a, in particular after switching to bypass mode, and/or during a time interval, said time interval being between 10 s and 80 s.

The robot may be moved over the photovoltaic system at a speed chosen to allow measuring a temperature of said diode before and after switching to bypass mode, so as to be able to observe a temperature variation of said diode if the diode is in an operational state. In particular, the robot may be moved over the photovoltaic system at a speed chosen to allow measuring a temperature of said diode before switching to bypass mode (threshold) and after switching, so as to be able to observe a temperature variation in said diode between these two moments if the diode is in an operational state.

Such a speed may be uniform throughout the robot's path or may vary. In particular, it may be zero for a predetermined duration at one or more predetermined positions of the robot.

The robot may move autonomously or may be controlled remotely.

At the moment when one or more diodes are switched to bypass mode, the robot may be ordered to remain in place for a dwell time that is a function of how quickly a hot spot appears on the diode(s), for example for a duration of between 20 s and 80 s.

The measurement may be carried out for a length of time of more than 10 s, in particular more than 20 s, to allow sufficient time for the diode(s) to heat up so that the heat released by the diode(s) diffuses to the front of the module, as the diode(s) are generally arranged on the rear of the module.

During the method, a temperature in at least one area, linked to the diode, of the photovoltaic module may be measured in order to have a reference temperature before and/or during the measurement of the diode temperature after the diode's activation, so as to monitor whether the photovoltaic module itself changes temperature due to a change in the irradiation received during the measurement.

The photovoltaic module may be connected to an inverter or a microinverter. In such case, the switch to bypass mode may be caused by the inverter or the microinverter, in particular when the maximum power generated by said string is less than the maximum power generated by an adjacent string of the same module or of an adjacent module connected in series. In this case, the inverter or microinverter sets the electrical operating point of the system.

Indeed, if shading or a defect appears on a cell or on a group of cells in a same string, the I/V curve will be deformed and the maximum power point, formed by the product of voltage times current according to the equation P=U*I, will change. If the shading or defects are significant, the maximum operating point is at the maximum power generated by an adjacent string of the same module or of an adjacent module connected in series, and this corresponds to a case where the diode is activated. It is this case that is caused by the shading induced to trigger the diode in order to be able to test it.

When a microinverter is present, the microinverter may perform a module-by-module optimization, so that the diode is triggered when the maximum power generated by the string or a group of strings with shading is lower than the maximum power generated by an adjacent string or an adjacent group of strings of the same module or of an adjacent module connected in series.

When the photovoltaic module is connected to an inverter, a plurality of modules is connected to the inverter: the inverter can optimize all of these modules. In this case, even with low shading, the condition where the maximum power generated by the string with shading is lower than the maximum power generated by an adjacent string of the same module or an adjacent module connected in series is generally satisfied, since all of the adjacent modules are functioning correctly.

The ambient illumination is preferably greater than 200 W/m², more preferably greater than 500 W/m², when implementing steps a and b of the method, and preferably less than 1000 W/m². Such a condition ensures that the photovoltaic module(s) are in an operational state. The ambient temperature is preferably less than or equal to 40° C. when implementing steps a and b of the method. If the irradiance does not exceed the threshold of 1000 W/m², and the ambient temperature, i.e. the outside temperature, is less than 40° C., this ensures that the heat released by the tested diode(s) is not masked by the heat of the module that is operating.

When there is insufficient illumination, in particular of certain cells, the method may include a step, simultaneous with step a, of artificially illuminating a portion of the cells in order to ensure that the photovoltaic module(s) are operating, in particular by using a lighting system.

The method may include a step, prior to shading step a, consisting of measuring the temperature of the surface of the photovoltaic module where the diode(s) that will be tested are located, in order to determine the initial temperature, it being possible to perform this measurement using a thermal sensor, in particular a thermal camera. This temperature may constitute said threshold.

Step b may be implemented using a thermal sensor, in particular a thermal camera. The method then preferably comprises a prior step of adjusting the thermal sensor, in particular the thermal camera, for example by performing a test on a bypass diode before implementing steps a and b.

The threshold indicated in step b of the method may correspond to measuring a temperature of the diode before switching to bypass mode, in particular just before switching.

The photovoltaic module may comprise a plurality of strings of photovoltaic cells connected in series, each string being connected to a bypass diode dedicated thereto. In this case, steps a and b are advantageously implemented on all or part of said plurality of strings of cells.

The cleaning robot has the initial function of cleaning the photovoltaic module(s). It is capable of being moved over the photovoltaic module(s) while being integral with the module(s). The robot is advantageously equipped, for implementing the method, with a shading system and a thermal sensor, in particular a thermal camera. The robot may also be equipped with a processing circuit for implementing step c, for example making use of a measurement processing algorithm in order to compare the temperature measurement(s) with said threshold and determine the operational state of the diode(s) being tested. Such a processing circuit may alternatively be external to the robot, the robot being able to exchange information with said processing circuit.

Preferably, step a is carried out so as to shade only a portion of the cells for a given string, another portion of the cells of said string remaining illuminated or being illuminated by ambient lighting or by an artificial lighting system.

The method may comprise, upstream of the implementation of step a, a step of optimizing the arrangement of a shading system intended for implementing step a, in order to cause the activation of the diode(s) concerned. This may allow adapting the shading system and its arrangement to the configuration of the photovoltaic system and/or to the type of cells in the modules.

Step a may be implemented so as to shade the photovoltaic module(s) symmetrically between the strings and/or within a same string. Such an embodiment may consist of shading cells of a string symmetrically by using two opaque portions of the shading system, with one portion, for example a central portion, of the cells not being shaded, in particular being arranged between these two opaque portions. The unshaded portion of the cells may be covered by a portion of the shading system that is transparent or that has an opening, in particular while connecting the two opaque portions. Such an embodiment may in particular be suitable for half-cell photovoltaic modules having two strings of cells in series and shared protection diodes.

The method may comprise, before implementing step a, a step of calibrating the shading. Such a step may consist of adapting the shading so that the maximum power of the shaded module coincides with the activation of the diode(s). Such a step may be carried out with a shading system adapted to the module(s) and a record of the I/V curves.

The temperature measurement in step b may be performed by an operator. The operator may, for example, perform the infrared thermography measurement at the rear of the module stand while the robot is passing over the module(s). This may be particularly suitable for small photovoltaic systems.

According to another aspect, in combination with some or all of the above, a device is proposed for implementing the method as defined above, comprising at least:
an equipment item, in particular autonomous or remote-controlled, preferably integral to the photovoltaic system and capable of moving, in particular in translation relative to the system, the equipment item being opaque so as to at least partially shade a portion of the cells of at least one string of at least one photovoltaic module of the system,
a thermal sensor for measuring a temperature of the diode, and
a processing circuit for comparing the temperature of the diode with a threshold and deducing a state of the diode from the comparison.

According to another aspect, in combination with some or all of the above, an equipment item of a device as defined above is provided, comprising a robot, in particular a cleaning robot for the photovoltaic module.

In this case, the robot may comprise at least one thermal camera and at least one shading system consisting of at least one flap attached to the robot or consisting of the robot itself.

The shading system may comprise a transparent and/or open portion to allow light to illuminate a portion of the photovoltaic cells linked to the diode that is to be tested.

The shading system may comprise one or more flaps comprising several, in particular two, opaque portions connected to each other by a transparent portion, and for example which are arranged symmetrically. In this case, said transparent portion may, in one particular embodiment, comprise an opening and at least two arms interconnecting the opaque portions.

The shading system may be detachable from the robot and/or movable relative thereto.

The flap of the shading system may consist of a film or a plate that is opaque to light. During the implementation of step a of the method, it may be arranged in front, behind, or to one or more sides of the robot.

In particular in the case where it is the robot itself that provides the shade, the device may comprise an integrated and controllable lighting system so as to illuminate a portion of the cells that are linked to the diode(s) to be tested. This makes it possible to avoid entirely shading any string of cells whose diode is to be tested, but allows there to be an illuminated portion and a shaded portion.

The robot may include an arm to which the thermal sensor, in particular the thermal camera, is attached, so as to allow it to access the rear face of the module(s) housing the diode(s), in particular if the ambient temperature is high and the sun is significantly heating the photovoltaic module(s), in which case the heat of the modules could prevent the detection of overheating diode(s).

The robot may comprise an integrated lighting system for illuminating a portion of the cells and activating the diode(s), in particular when the ambient lighting is insufficient.

In particular, when the photovoltaic cells are thin-film cells, the shading system may be configured according to the arrangement of the cells, in order to ensure the activation conditions for the diode(s).

### BRIEF DESCRIPTION OF DRAWINGS

Other features, details and advantages will become apparent upon reading the detailed description below, and upon analyzing the attached drawings, in which:

FIG. 1 schematically shows an example of a photovoltaic module on which the method according to the invention can be implemented.

FIG. 2 is a graph illustrating curves of intensity versus voltage, recorded for a photovoltaic module as a function of the shaded surface of the module.

FIG. 3 schematically shows a photovoltaic module with a string of cells shaded at 25% which allowed obtaining one of the curves in FIG. 2.

FIG. 4 schematically shows a photovoltaic module with a string of cells shaded at 50% which allowed obtaining another of the curves in FIG. 2.

FIG. 5 schematically shows a photovoltaic module with a string of cells shaded at 75% which allowed obtaining another of the curves in FIG. 2.

FIG. 6 is a graph illustrating the curve of intensity versus voltage, recorded for the module of FIG. 5.

FIG. 7 is a graph illustrating the curve of power versus voltage, recorded for the module of FIG. 5.

FIG. 8 schematically shows a top view of a photovoltaic module on which the method according to one embodiment of the invention is implemented.

FIG. 9 schematically shows a cross-section of the photovoltaic module illustrated in FIG. 8, during implementation of the method.

FIG. 10 is a photograph of a photovoltaic system on which the method according to the invention is implemented.

FIG. 11 is a schematic top view of photovoltaic modules on which the method is implemented according to one embodiment.

FIG. 12 is a schematic top view of photovoltaic modules on which the method is implemented according to one embodiment.

FIG. 13 is a schematic top view of photovoltaic modules on which the method is implemented according to one embodiment.

FIG. 14 is a schematic top view of photovoltaic modules on which the method is implemented according to one embodiment.

FIG. 15 is a schematic top view of photovoltaic modules on which the method is implemented according to one embodiment.

FIG. 16 is a schematic top view of photovoltaic modules on which the method is implemented according to one embodiment.

FIG. 17 is a schematic top view of photovoltaic modules on which the method is implemented according to one embodiment.

FIG. 18 is a schematic top view of the photovoltaic modules of FIG. 17 after the robot has advanced.

FIG. 19 is a schematic top view of photovoltaic modules on which the method is implemented according to one embodiment.

FIG. 20 is a schematic top view of the photovoltaic modules of FIG. 19 after the robot has advanced.

FIG. 21 is a schematic top view of photovoltaic modules on which the method is implemented according to one embodiment.

FIG. 22 is a schematic top view of the photovoltaic modules of FIG. 21 after the robot has advanced.

FIG. 23 is a schematic top view of photovoltaic modules on which the method is implemented according to one embodiment.

FIG. 24 is a schematic top view of photovoltaic modules on which the method is implemented according to one embodiment.

FIG. 25 is a schematic top view of photovoltaic modules on which the method is implemented according to one embodiment.

FIG. 26 schematically illustrates a perspective view of one example of a device according to one embodiment comprising a cleaning robot for implementing the method according to the invention.

FIG. 27 schematically illustrates a perspective view of the device of FIG. 26 with the deployment of a shading system.

### DETAILED DESCRIPTION

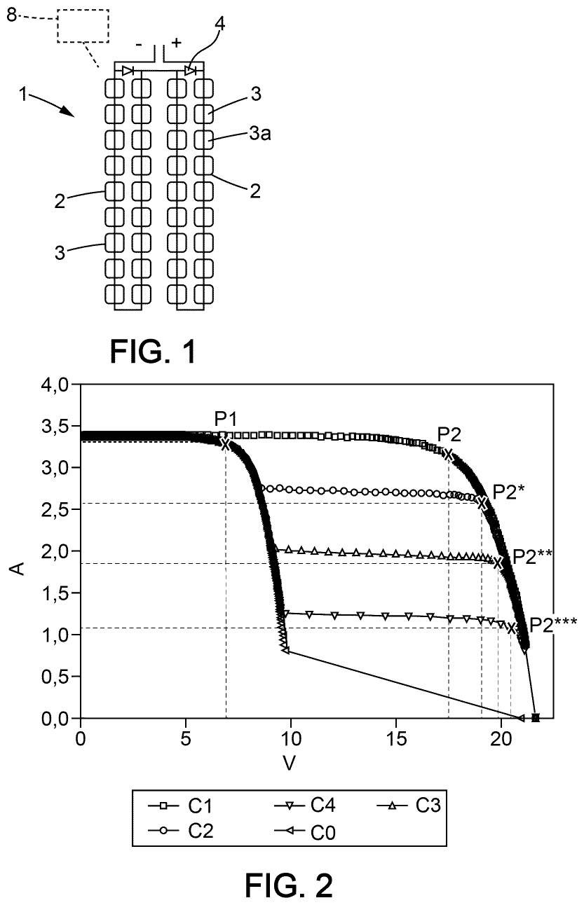

Reference is now made to FIG. 1. In this figure, a top view of a photovoltaic module 1 is schematically represented, comprising two strings 2 each comprising a plurality of photovoltaic cells 3, eighteen cells 3 for each string 2 in this example. Cells 3 are interconnected in series. String 2 illustrated in FIG. 1 comprises a cell 3a which has been shaded. A bypass diode 4 is associated with each of strings 2 such that, when one or more cells 3 of string 2 are shaded, the current no longer flows through cells 3 of string 2 but through diode 4. Diode 4 is therefore activated, becoming conductive. A bypass has been established.

In this example, module 1 is connected to a microinverter 8. When strings 2 are not shaded, microinverter 8 selects the maximum power point P1 of one string 2 and P2 of an adjacent string, as can be seen respectively in curves C0 and C1 illustrated in FIG. 2.

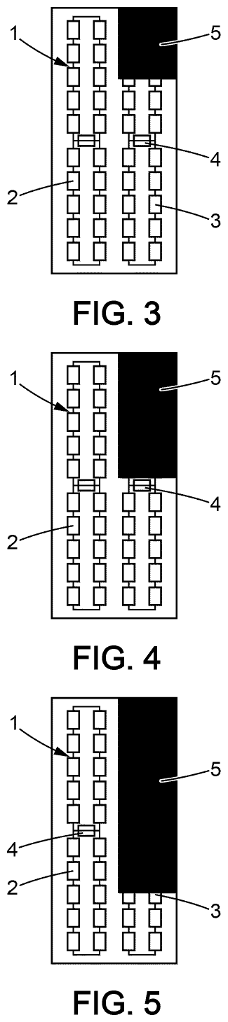

On the other hand, if a portion of string 2 is shaded by a shading system 5 as illustrated in FIGS. 3 to 5, then the power decreases as illustrated in the various curves C2 to C4 of FIG. 2. Thus, P2* illustrates the maximum power point obtained when 25% of the surface area of cells 3 are shaded in a string 2 as illustrated in FIG. 3. P2** illustrates the maximum power point obtained when 50% of cells 3 are shaded as illustrated in FIG. 4, while P2*** illustrates the maximum power point obtained when 75% of cells 3 are shaded as illustrated in FIG. 5.

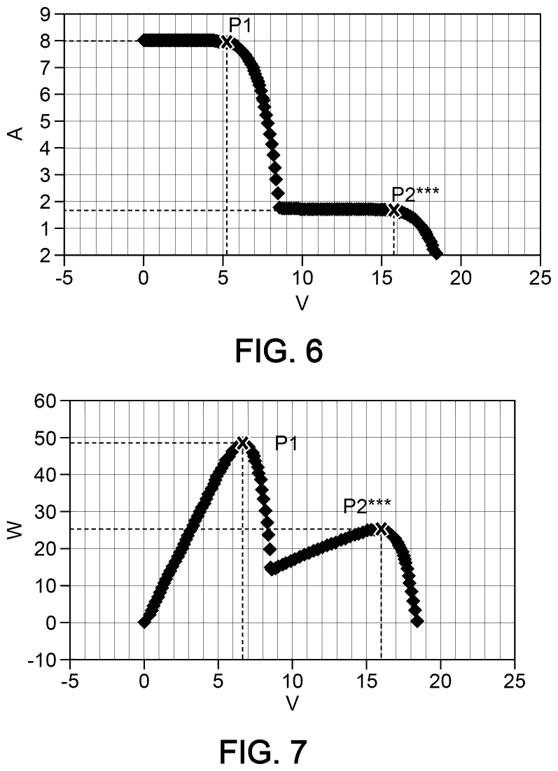

The curves shown in FIGS. 6 and 7 respectively represent the I/V curve of the module shown in FIG. 5 and the curve of the power (in watts) versus voltage (in volts) for the same module illustrated in FIG. 5.

Microinverter 8 is programmed to trigger the switch to bypass mode, i.e. to activate the bypass diode 4, when P1>P2 (P2 being in the form P2, P2*, P2**, or P2*** depending on the shading of string 2).

The method according to the invention uses these properties to allow detecting a defective diode.

Indeed, the method according to the invention is a method for testing at least one bypass diode 4 in a photovoltaic system 100 comprising at least one photovoltaic module 1 that is in operation, photovoltaic module 1 comprising at least one string 2 of photovoltaic cells 3, in this case three strings 2 of twenty photovoltaic cells 3, each being connected to a dedicated bypass diode 4 for each string 2.

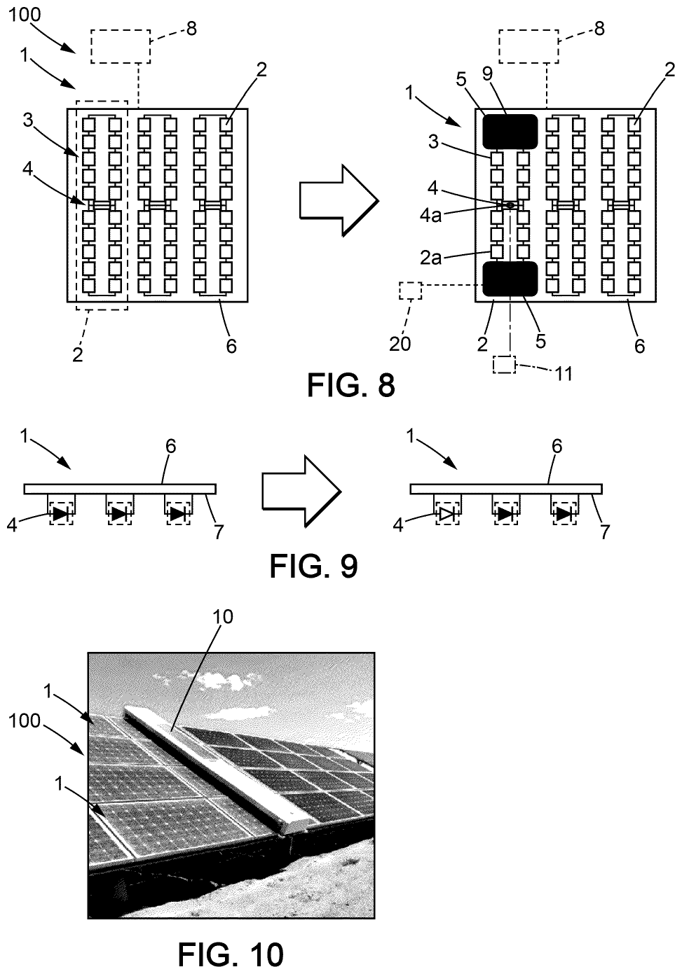

As can be seen in FIG. 8, the method comprises the step of shading, by means of a shading system 5 which in this example comprises two opaque flaps 9, at least a portion of cells 3 of string 2 until this causes a switch to bypass mode through diode 4 dedicated to string 2. The switch causes diode 4 to increase in temperature if diode 4 is in an operational state. Such bypassing may be triggered by microinverter 8. The method also comprises the step of measuring, in particular using a thermal sensor 11, at least one temperature of diode 4 and a step of comparing, in particular using a processing circuit 20, the measured temperature with a threshold in order to deduce a state of diode 4, i.e. whether diode 4 is in an operational state or whether it is defective.

As can be seen in FIG. 9, in this example diodes 4 are located on rear face 7 of photovoltaic module 1, front face 6 being the one that is visible in FIG. 8.

Microinverter 8 performs a module-by-module optimization, such that the triggering of diode 4 occurs when the maximum power generated by shaded string 2 is lower than the maximum power generated by an adjacent string 2 of the same module 1 or of an adjacent module 1 connected in series.

In the example of FIG. 8, system 100 comprises a single photovoltaic module 1.

In this example, the ambient illumination is greater than 200 W/m during implementation of the method and is less than 1000 W/m². Such a condition ensures that photovoltaic module(s) 1 are in operating condition. The ambient temperature is preferably less than or equal to 40° C. during implementation of the method.

The activation of diode 4, if it is in operational state, will generate a localized heating which will be detected by the temperature measurement and will be characterized by comparing it to the threshold.

If the diode is not in an operational state, no temperature variation will be observed there.

If the temperature of diode 4 is measured at the moment before switching to bypass mode, which is the moment when it becomes conductive, and if this temperature that constitutes the threshold is substantially equal to the ambient temperature and no variation in the temperature of diode 4 is observed after switching, then it can be concluded that diode 4 is defective, being stuck in open circuit mode.

If the temperature of diode 4, measured after switching to bypass mode, is compared to the threshold corresponding to the temperature of diode 4 measured at the moment before switching, and if this temperature that constitutes the threshold is higher than the ambient temperature and no variation in the temperature of the diode is observed after switching, then it can be concluded that the diode is defective, being stuck in short circuit mode.

The detection of one or more defective diodes 4 may make it possible to prevent potential safety hazards and/or to improve the electrical production of the system comprising a plurality of photovoltaic modules, i.e. the solar power plant. In addition, other related defects such as one or more defective photovoltaic cells may be detected using the method according to the invention, in particular by taking temperature measurements.

The method may be implemented using an equipment item, autonomous or remote-controlled, that is configured to be integral with photovoltaic system 100 and to move or be moved relative to the modules 1 thereof. The equipment item may be a robot, in this example a cleaning robot 10 for photovoltaic modules 1, of which an example is illustrated in FIG. 10. Such a cleaning robot 10, in a manner that is known per se, is provided for periodically cleaning photovoltaic modules 1 of the photovoltaic system 100 comprising a plurality of photovoltaic modules 1 in FIG. 10. Cleaning robot 10 may advantageously be used to implement the method according to the invention. This makes it possible to avoid significantly increasing maintenance costs, as cleaning robot 10 is already being used for the periodic maintenance of photovoltaic modules 1.

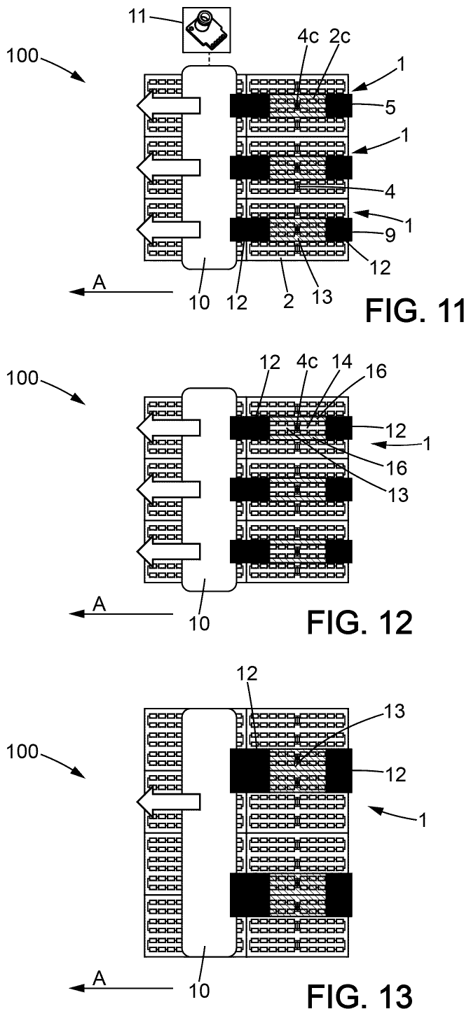

In the example illustrated in FIGS. 11 to 16, photovoltaic system 100 comprises a plurality of photovoltaic modules 1 arranged side by side from bottom to top as well as laterally. Robot 10 covers the surface of system 100, from bottom to top. Robot 10 is moved in the direction of advancement A illustrated by the arrows in these figures. At the rear of cleaning robot 10 and fixed thereto is arranged a shading system 5 for implementing, with the aid of shading system 5, the step of shading at least a portion of cells 3 of one or more strings 2 until causing a switch to bypass mode through each diode 4 dedicated to this or these strings 2. Cleaning robot 10 is also equipped with a thermal sensor, in this example consisting of a thermal camera 11, illustrated schematically only in FIG. 11 but present in all of these embodiments of FIGS. 11 to 16.

Such a thermal camera 11 makes it possible to implement at least the step of measuring at least one temperature of diode 4. Robot 10 is further configured to compare the measured temperature with a threshold in order to deduce a state of the diode or diodes 4, i.e. whether diode 4 is in an operational state or is defective. Alternatively, robot 10 is connected to a processing circuit which allows implementing this step of comparing the measured temperature with a threshold in order to deduce a state of diode(s) 4.

More particularly, in the embodiment illustrated in FIG. 11, system 100 comprises, in a direction transverse to the direction of advancement A, three photovoltaic modules 1. Each photovoltaic module 1 comprises three strings 2 of twenty cells 3 each, each also comprising a bypass diode 4. Robot 10 comprises a shading system 5 comprising three flaps 9 each comprising an opaque portion 12 and a transparent portion 13, opaque portion 12 being split into two parts one on either side of transparent portion 13. The shading formed by opaque portions 12 is symmetrical in this example, which may allow more precise control over the activation of the diode. Each flap 9 covers a central string 2c of a photovoltaic module 1, with the opaque portions 12 shading a portion of central string 2c until the switch to bypass mode is triggered, and therefore activating diode 4c dedicated to central string 2c. The speed of robot 10 is adapted to allow for this switch, robot 10 being for example stopped in the illustrated position for a length of time exceeding 10 s, for example exceeding 20 s, and less than 80 s. This makes it possible to activate the three diodes 4c of central strings 2c of modules 1.

The embodiment of FIG. 12 differs from that of FIG. 11 in that transparent portion 13 comprises an opening 14 formed between two transparent arms 16 interconnecting the two opaque portions 12. Opening 14 may facilitate detecting the heating of diode 4c.

In the example of FIG. 13, the number of photovoltaic modules 1 of system 100 is equal to four in a direction transverse to the direction of advancement A. Furthermore, shading system 5 comprises two flaps 9 each comprising an opaque portion 12 and a transparent portion 13, opaque portion 12 being split into two parts one on either side of transparent portion 13. Each opaque portion 12 covers two portions of two adjacent strings 2 belonging to two different and adjacent modules 1. Thus, the two flaps 9 allow simultaneously activating four diodes 4 belonging to four different modules 1. The shading formed by opaque portions 12 is symmetrical in this example, which may allow more precise control over the activation of diodes 4.

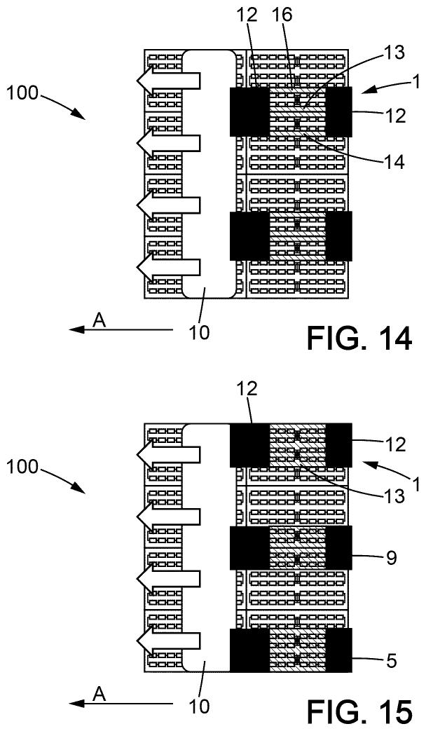

The embodiment of FIG. 14 differs from that of FIG. 13 in that transparent portion 13 comprises two openings 14 formed between two transparent arms 16 interconnecting the two opaque portions 12. Openings 14 may make facilitate detecting the heating of the diodes 4 concerned.

In the embodiment of FIG. 15, illustrating a system 100 similar to that of FIG. 13 or 14, shading system 5 comprises three flaps 9 each partially covering two adjacent strings 2. Two flaps 9 each cover two adjacent strings 2 of a same module 1, causing the switch to bypass mode through two diodes 4 of a same module 1, while central flap 9 covers two adjacent strings 2 of two different modules 1, causing a bypass through only one of diodes 4 of each of modules 1.

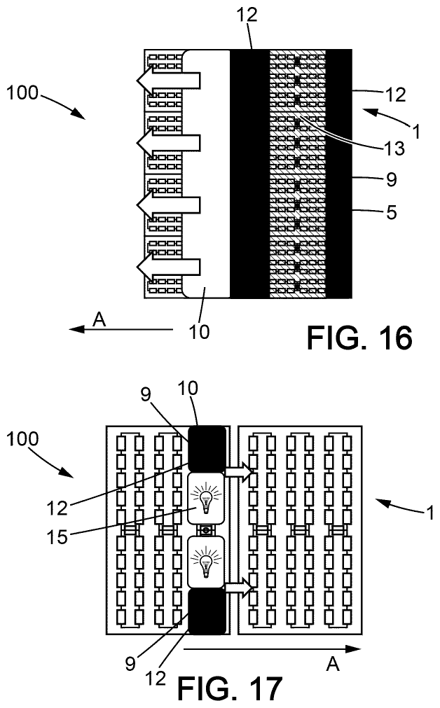

The embodiment of FIG. 16 differs from that of FIG. 15 in that it comprises a shading system 5 covering the entire width, transverse to the direction of advancement A, of robot 10 and therefore of system 100. Shading system 5 comprises a single flap 9 comprising an opaque portion 12 having two parts symmetrically surrounding a central transparent portion 13. All diodes 4 of all modules 1, arranged from bottom to top of system 100, are thus activated simultaneously and may therefore be tested simultaneously.

In the embodiments illustrated in FIGS. 17 to 22, system 100 comprises a succession of photovoltaic modules 1 arranged side by side along the direction of advancement A of robot 10. Each module 1 comprises three strings 2 of twenty cells 3 each. In the embodiments of FIGS. 11 to 16, strings 2 extend parallel to the direction of advancement A. In the embodiments of FIGS. 17 to 22, strings 2 extend transversely, perpendicularly to this direction of advancement A.

Still concerning these examples of FIGS. 17 to 22, robot 10 itself is shading system 5, the system not being deployed externally to robot 10 but consisting of part of the robot. In addition, cleaning robot 10 comprises a lighting system 15 in order to illuminate a portion of the shaded cells and participate in triggering diodes 4. Lighting system 15 may be used to compensate for a lighting deficit. In the present case, it is used to compensate for shading formed by part of robot 10 over an area of string 2 that one does not wish to shade, in order to activate diodes 4.

In the example illustrated in FIG. 17, shading system 5 comprises two opaque flaps 9 arranged symmetrically around diode 4 of a string 2 of a module 1. The portion of string 2 that is not intended to be shaded is illuminated by lighting system 15 in order to ensure that diode 4 dedicated to string 2 is activated.

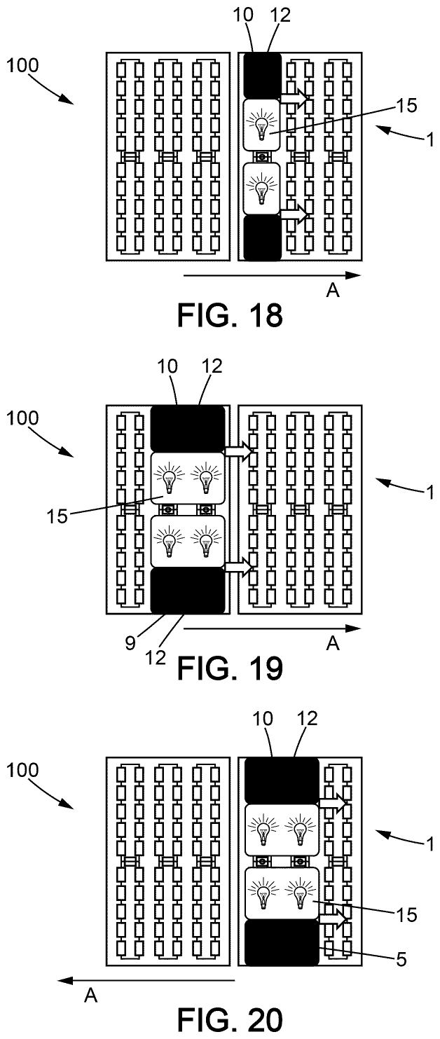

FIG. 18 illustrates the movement of robot 10 of FIG. 17 to the next string 2 of the adjacent module 1 in order to cause a bypass through the diode 4 dedicated to this next string 2, so that its state can be checked.

In the embodiment of FIGS. 19 and 20, two adjacent strings 2 of a module 1 are concerned by the implementation of the method according to the invention, robot 10 forming a shading system 5 symmetrically covering two portions of the two strings 2, one on either side of a central portion of these strings, said central portion being illuminated by lighting system 15. Thus, two diodes 4 dedicated to the strings 2 concerned can be tested.

FIG. 20 illustrates the movement of cleaning robot 10 of FIG. 19 to the next two strings 2 of adjacent module 1 in order to cause the switch to bypass mode through the diodes 4 dedicated to these two next strings 2, so that its state can be checked.

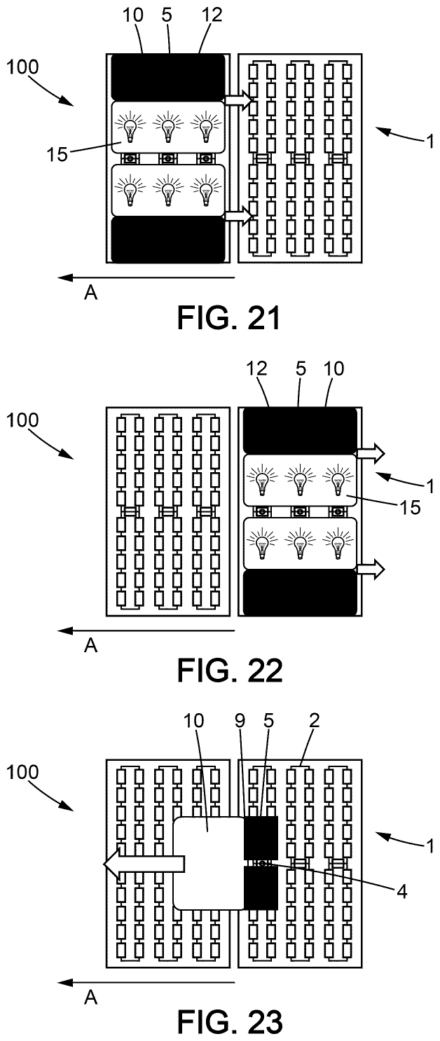

In the embodiment in FIGS. 21 and 22, three strings 2 of a same module 1 are concerned by the implementation of the method according to the invention, robot 10 forming a shading system 5 symmetrically covering two portions of the three strings 2, one on either side of a central portion of these strings, said central portion being illuminated by lighting system 15. Thus, the three diodes 4 of module 1, which are dedicated to these strings 2 of module 1, are tested.

FIG. 22 illustrates the movement of robot 10 of FIG. 21 to the next three strings 2 of adjacent module 1 in order to cause the switch to bypass mode through diodes 4 of adjacent module 1 which are dedicated to these three strings 2, so that their state can be checked.

In the embodiments illustrated in FIGS. 23, 24, and 25, robot 10 does not extend over the entire width transverse to the direction of advancement A, of modules 1 of system 100. Furthermore, system 100 comprises a single module 1 in this width, as it does in FIGS. 17 to 22. In addition, shading system 5 comprises two flaps 9 each comprising only one opaque portion 12 which is deployed at the rear of robot 10 in order to shade a portion of cells 3.

In the embodiment of FIG. 23, a portion, in particular a half, of cells 3 of a string 2 is shaded so as to cause a switch to bypass mode and therefore the activation of diode 4 dedicated to this string 2.

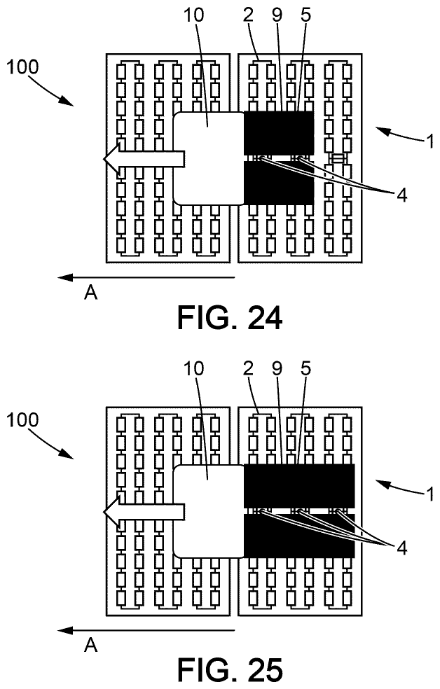

In the embodiment of FIG. 24, a portion, in particular a half, of cells 3 of two adjacent strings 2 is shaded so as to cause a switch to bypass mode and therefore the activation of the two diodes 4 associated with these strings 2.

Finally, in the embodiment of FIG. 25, a portion, in particular a half, of cells 3 of the three strings 2, i.e. all strings 2 of module 1 in this example, is shaded so as to cause a switch to bypass mode and therefore the activation of the three diodes 4 of module 1.

Activation of diode(s) 4 constitutes the first step before measuring the temperature of diode 4 or diodes 4 in order to be able to compare it/them with a threshold and deduce whether or not diode(s) 4 are in an operational state.

The step of measuring the temperature is advantageously carried out by robot 10, which is equipped with at least one thermal sensor, in particular a thermal camera 11. Such a thermal camera 11 is capable of measuring the temperature of diode 4 or of several diodes 4, for example before and after switching to bypass mode, and/or of the surface of the module, an ambient temperature, etc.

The step of comparing the measured temperature with a threshold and deducing the state of diode 4 may be performed by robot 10 itself if it is equipped with a processing circuit, or by an external processing circuit with which robot 10 may communicate to exchange information.

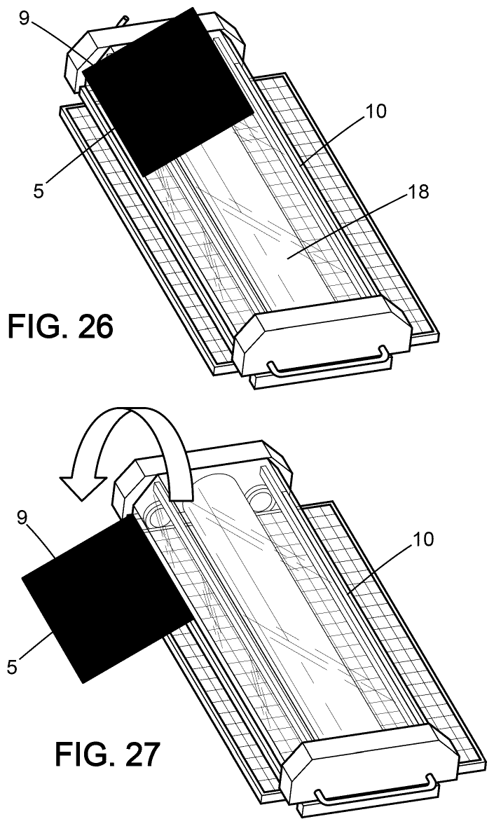

In the embodiment illustrated in FIGS. 26 and 27, cleaning robot 10 comprises a shading system 5 consisting of a flap 9 that is rotatable relative to the body 18 of robot 10 in order to move from a folded position illustrated in FIG. 26 to a deployed position illustrated in FIG. 27. In the folded position, shading system 5 is not capable of shading a portion of cells 3, while the deployed position allows covering a portion of cells 3 when robot 10 is attached to a photovoltaic system 100 and/or to at least one photovoltaic module 1.

Of course, the invention is not limited to the examples just described.

The robot may be autonomous or remotely controlled.

When there are several photovoltaic modules 1, their management may be carried out by an inverter instead of by a microinverter. A plurality of modules is then connected to the inverter. The inverter may optimize all of these modules. In such case, even with low shading, the condition of the maximum power generated by the string with shading being less than the maximum power generated by an adjacent string of the same module or of an adjacent module connected in series is generally satisfied since all of the adjacent modules are operating correctly.

Any robot or equipment item that is an autonomous or remote-controlled member, other than cleaning robot 10, dedicated or not dedicated to the implementation of the method, may be used in the invention.

The method may include a step prior to the shading step, consisting of measuring the temperature of the surface 6 of photovoltaic module 1 where the diode(s) 4 that will be tested are located, in order to determine the initial temperature, this measurement being able to be carried out using a thermal sensor, in particular a thermal camera 11. This temperature may constitute said threshold.

The method may include, before shading, a step of calibrating the shading. Such a step may consist of adapting the shading so that the maximum power of the shaded module 1 coincides with the activation of diode(s) 4. Such a step may be carried out with a shading system 5 adapted to module 1 and a record of the I/V curves.

During the method, a temperature in at least one area linked to diode 4 of photovoltaic module 1 may be measured, for example as a threshold, in order to have a reference temperature before and/or while measuring the temperature of diode 4, after the diode's activation, so as to monitor whether photovoltaic module 1 itself changes temperature due to a change in the irradiation received during the measurement.

The step of measuring the temperature of diode 4, after shading, may be implemented using a thermal sensor, in particular a thermal camera. The method then preferably comprises a prior step of adjusting the thermal sensor, in particular the thermal camera, for example by performing a test on a bypass diode 4 before implementing the steps of shading and measuring the temperature of diode 4.

1-11. (canceled)

12. A method for testing at least one bypass diode in a photovoltaic system comprising at least one photovoltaic module that is in operation, said photovoltaic module comprising at least one string of photovoltaic cells that are connected to a bypass diode (4) dedicated to said string, the method comprising:
a. shading a portion of the cells of said string so as to cause a switch to bypass mode through said diode, said switch causing an increase in the temperature of the diode if the diode is in an operational state;
b. measuring at least one temperature of the diode; and
c. comparing the measured temperature with a threshold in order to deduce a state of said diode.

13. The method according to claim 12, wherein at least steps a and b are implemented using a robot, in particular a cleaning robot for photovoltaic modules, said robot being configured to shade said portion of the cells and comprising a thermal sensor, in particular a thermal camera, for measuring said at least one temperature of the diode.

14. The method according to claim 13, wherein the robot is moved over the photovoltaic system at a speed chosen to allow measuring a temperature of said diode before and after switching to bypass mode, so as to be able to observe a temperature variation of said diode if the diode is in operational state.

15. The method according to claim 12, wherein said photovoltaic module is connected to an inverter or a microinverter and wherein the switch to bypass mode is caused by the inverter or the microinverter, in particular when the maximum power generated by said string is less than the maximum power generated by an adjacent string of the same module or of an adjacent module connected in series.

16. The method according to claim 12, wherein the ambient illumination is greater than 200 W/m², and preferably less than 1000 W/m², when implementing steps a and b of the method, and wherein the ambient temperature is preferably less than or equal to 40° C. when implementing steps a and b of the method.

17. The method according to claim 12, step b being implemented using a thermal sensor, in particular a thermal camera, the method comprising a prior step of adjusting the thermal sensor, in particular the thermal camera, in particular by performing a test on a bypass diode before implementing steps a and b.

18. The method according to claim 12, wherein said threshold corresponds to measuring a temperature of the diode before switching to bypass mode.

19. The method according to claim 12, said photovoltaic module comprising a plurality of strings of photovoltaic cells connected in series, each string being connected to a bypass diode dedicated thereto, wherein the steps a and b are implemented on all or part of said plurality of strings of cells.

20. A device for implementing the method according to claim 12, comprising at least:
an opaque equipment item for at least partially shading a portion of the cells of at least one string of at least one photovoltaic module of the photovoltaic system,
a thermal sensor for measuring a temperature of the diode, and
a processing circuit for comparing the temperature of the diode with a threshold and deducing a state of the diode from the comparison.

21. An equipment item of a device according to claim 20, comprising a robot, in particular a cleaning robot for the photovoltaic module.

22. The equipment item according to claim 21, wherein the robot comprises at least one thermal camera and at least one shading system consisting of at least one flap attached to the robot or consisting of the robot itself.
